(19) United States
(12) Patent Application Publication
(10) Pub. No.: US 2016/0141272 A1
(43) Pub. Date: May 19, 2016

(54) SEMICONDUCTOR DEVICE AND METHOD OF MANUFACTURING SAME

(71) Applicant: PS4 Luxco S.a.r.l., Luxembourg (LU)

(72) Inventor: Susumu Inakawa, Tokyo (JP)

(21) Appl. No.: 14/899,514

(22) PCT Filed: Jun. 5, 2014
(86) PCT No.: PCT/JP2014/064924

§ 371 Date: Dec. 17, 2015

(30) Foreign Application Priority Data
Jun. 18, 2013 (JP) 2013-127216

(51) Int. Cl. H01L 25/065; H01L 25/00; H01L 21/56; H01L 23/31; H01L 23/498; H01L 23/00

(52) U.S. Cl. CPC H01L 25/0657; H01L 23/49838; H01L 24/49; H01L 24/85; H01L 21/56; H01L 23/3107; H01L 25/50; H01L 2225/0651; H01L 2225/06555; H01L 2225/06506; H01L 2224/48227; H01L 2924/10161; H01L 2224/48091; H01L 2224/48145; H01L 2224/48463; H01L 2224/85207

(57) ABSTRACT

A semiconductor device which is provided with: a wiring substrate which has a first region, and a relay pad and a connection pad that are arranged outside the first region; a first semiconductor chip which has an electrode pad that is formed on one surface, and which is mounted on the first region of the wiring substrate; a first wire that connects the electrode pad and the relay pad with each other; and a second wire that connects the relay pad and the connection pad with each other.

### TECHNICAL FIELD

The present invention relates to a semiconductor device and to a method for manufacturing same, and in particular the present invention relates to a ball grid array (BGA) semiconductor device and to a method for manufacturing same.

### BACKGROUND

A conventional BGA semiconductor device comprises a semiconductor chip mounted on a wiring board, and bonding wires for electrically connecting electrode pads on the semiconductor chip and connection pads on the wiring board.

Examples of associated technology include JP 2013-38296 A (Patent Document 1) and JP 2000-124391 A (Patent Document 2).

Patent Document 1 describes a multi-chip package (MCP) semiconductor device in which a plurality of semiconductor chips are mounted. Furthermore, Patent Document 2 describes an arrangement in which electrodes of first and second semiconductor chips and a wiring board are continuously connected by wire.

### Patent Documents

Patent Document 1: JP 2013-38296 A

Patent Document 2: JP 2000-124391 A

### SUMMARY OF THE INVENTION

### Problem to be Solved by the Invention

There are problems in the conventional technology described above if there are a large number of electrode pads disposed on one side of a semiconductor chip mounted on a wiring board, or if a large number of electrode pads are disposed on the same side on a plurality of semiconductor chips, because it is difficult to route the wiring pattern on the wiring board or the wiring takes a circuitous route.

In this regard, the present invention provides a semiconductor device which enables a wiring pattern on a wiring board to be easily routed, and a method for manufacturing same.

### Means for Solving the Problem

A semiconductor device according to a mode of the present invention is characterized in that it comprises:

a wiring board having a first region, and first and second connection pads disposed outside the first region;

a first semiconductor chip which has a first electrode formed on one surface thereof and is mounted in the first region of the wiring board;

a first wire for connecting the first electrode and the first connection pad; and

a second wire for connecting the first connection pad and the second connection pad.

Furthermore, a method for manufacturing a semiconductor device according to a mode of the present invention is characterized in that it comprises the following steps:

a step in which a wiring board having, on one surface, a first region, and first and second connection pads disposed outside the first region is prepared;

a step in which a first semiconductor chip which has a first electrode formed on one surface thereof is mounted in the first region of the wiring board;

a step in which the first electrode and the first connection pad are connected by means of a first wire; and

a step in which the first connection pad and the second connection pad are connected by means of a second wire.

### Advantage of the Invention

According to the present invention, a wiring pattern on a wiring board can be easily routed.

### BRIEF DESCRIPTION OF THE FIGURES

FIG. 1 is a plan view showing the schematic configuration of a semiconductor device according to a first mode of embodiment of the present invention;

FIG. 2 is a view in cross section showing the schematic configuration between A-A′ in FIG. 1;

FIG. 3 is a view in cross section showing the schematic configuration of a variant example of the semiconductor device according to the first mode of embodiment of the present invention;

FIG. 4 is a view in cross section showing the assembly flow for the semiconductor device according to the first mode of embodiment of the present invention;

FIG. 5 is a view in cross section showing the processing flow for wire bonding;

FIG. 6 is a plan view showing the schematic configuration of a semiconductor device according to a second mode of embodiment of the present invention;

FIG. 7 is a view in cross section showing the schematic configuration between B-B′ in FIG. 6;

FIG. 8 is a plan view showing the schematic configuration of a semiconductor device according to a third mode of embodiment of the present invention;

FIGS. 9(a) and (b) are views in cross section showing the schematic configuration between C-C′ and between D-D′ in FIG. 8, respectively;

FIG. 10 is a view in cross section showing the processing flow for wire bonding according to the third mode of embodiment of the present invention; and

FIG. 11 is a plan view showing the schematic configuration of a variant example of the semiconductor device according to a mode of embodiment of the present invention.

### MODE FOR IMPLEMENTING THE INVENTION

Preferred modes of embodiment of the present invention will be described in detail below with reference to the figures.

### First Mode of Embodiment

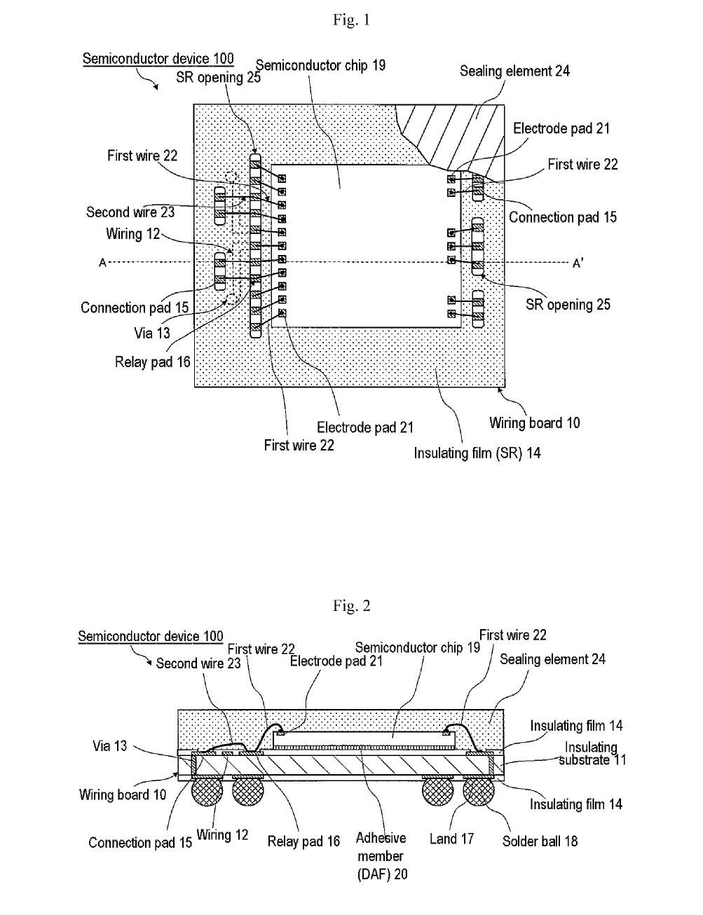

The configuration of a semiconductor device according to a first mode of embodiment of the present invention will be described with reference to FIG. 1 and FIG. 2.

Here, FIG. 1 is a plan view showing the schematic configuration of the semiconductor device according to the first mode of embodiment of the present invention. FIG. 2 is a view in cross section showing the schematic configuration between A-A′ in FIG. 1.

As shown in FIG. 1 and FIG. 2, a semiconductor device 100 according to a first mode of embodiment has the shape of a substantially rectangular plate and comprises a wiring board 10 on which a predetermined wiring pattern is formed. The wiring board 10 has an insulating substrate 11 comprising a glass epoxy substrate or a prepreg. A predetermined wiring pattern (wiring) 12 is formed on an upper surface (one surface) and a lower surface (other surface) of the insulating substrate 11, and two layers of the wiring 12 are electrically connected by means of vias 13.

Furthermore, an insulating film 14 (e.g., a solder resist film) is formed on the upper surface and the lower surface of the insulating substrate 11, and part of the wiring 12 is exposed from the insulating film 14. The parts of the wiring 12 on the upper surface side of the wiring board 10 which are exposed from an opening (SR opening 25) in the insulating film 14 form a connection pad 15 and a relay pad 16, and the parts of the wiring 12 on the other surface side of the wiring board 10 which are exposed from an opening (SR opening 25) in the insulating film 14 form lands 17. A solder ball 18 is mounted on the lands 17.

Furthermore, a semiconductor chip 19 is mounted on the upper surface of the wiring board 10 with an adhesive member (DAF) 20 interposed. The semiconductor chip 19 is a memory chip in which a memory circuit is formed, for example, and a plurality of electrode pads 21 are arranged along short sides of the rectangular shape, for example. DQ-system electrode pads 21 are mainly disposed on one of the short sides, while command address-system electrode pads 21 are disposed on the other short side, the number of electrode pads 21 on the short side which is the DQ-system side being greater than the number of electrode pads 21 on the command address-system side.

The electrode pads 21 and the relay pad 16 are connected by means of a first wire 22, and the relay pad 16 and the connection pad 15 are connected by means of a second wire 23. Here, the second wire 23 is disposed in such a way as to straddle the wiring 12. A sealing element (sealing resin) 24 is then formed on the upper surface of the wiring board 10 in such a way as to cover at least the semiconductor chip 19.

In the abovementioned configuration, part of the wiring 12 is disposed in such a way as to lie across one surface (the upper surface) of the wiring board 10 on which the DQ side having a large number of electrode pads 21 is disposed, so where it would be difficult to route the wiring 12 or the wiring would have a circuitous route, the relay pad 16 is disposed between the electrode pads 21 of the semiconductor chip 19 and the connection pad 15, and the second wires 23 straddle another part of the wiring 12 that lies across the wiring board 10.

The problem of routing the wiring 12 could be solved by changing the wiring board 10 from two layers of wiring to three or more layers of wiring, but this would increase the cost of manufacturing the wiring board 10 (increase the cost of the semiconductor device 100) and the thickness of the wiring board 10 (thickness of the semiconductor device 100) would also increase if the number of layers were increased. However, by adopting a configuration as in the first mode of embodiment in which the relay pad 12 is disposed in a region where the wiring 12 is densely packed and the second wires 23 straddle the other wiring 12, the problem of routing the wiring 12 can be easily solved without increasing the cost of the wiring board 10 or the thickness thereof.

In addition, the degree of freedom in the design layout of the wiring board 10 can be improved by providing the relay pad 16 on the wiring board 10. Furthermore, the length of the wiring can be reduced by a connection employing the second wires 23 which pass over the other wiring 12, without any rerouting.

Furthermore, if the remote connection pad 15 were wire-connected without the use of the relay pad 16, the length of the wire would increase and there would be a greater risk of wire sweep or wire short-circuiting during molding, but according to the first mode of embodiment, the first wire 22 and the second wire 23 are also connected to the relay pad 16 so the length of the wire is the same but the length of the looped portions is reduced and therefore it is possible to reduce the risk of wire sweep or wire short-circuiting.

In addition, in order to connect wires to the relay pad 16, the wires can be tensioned in such a way as to bend between the electrode pads 21 and the connection pad 15 via the relay pad 16, and therefore the risk of wire short-circuiting can be further reduced.

Furthermore, according to the first mode of embodiment, the first wire 22 which connects the electrode pad 21 of the semiconductor chip 19 and the relay pad 16 of the wiring board 10, and the second wire 23 which connects the relay pad 16 and the connection pad 15 of the wiring board 10 are continuously formed by a single wire. It is therefore possible to reduce the number of times of forming a ball at the tip end of the wire during wire bonding and the amount of wire used can be reduced. Au wire is used, so it is possible to reduce the cost by reducing the amount of Au used.

It should be noted that FIG. 2 illustrates a case in which the first wire 22 which connects the electrode pad 21 of the semiconductor chip 19 and the relay pad 16 of the wiring board 10, and the second wire 23 which connects the relay pad 16 and the connection pad 15 of the wiring board 10 are formed by a single wire.

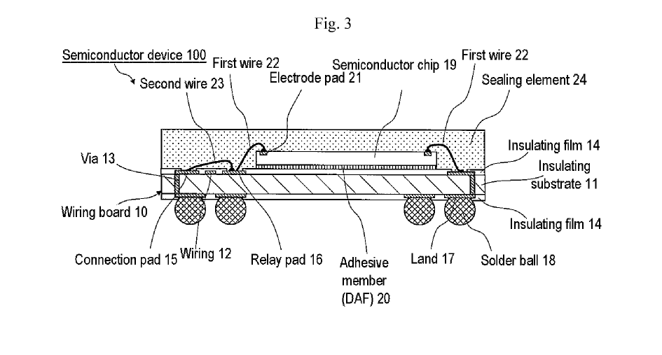

As shown in FIG. 3, however, the first wire 22 which connects the electrode pad 21 of the semiconductor chip 19 and the relay pad 16 of the wiring board 10 and the second wire 23 which connects the relay pad 16 and the connection pad 15 of the wiring board 10 may be formed by separate wires. When they are formed by separate wires, there is a greater degree of freedom in the position where the relay pad 16 is arranged.

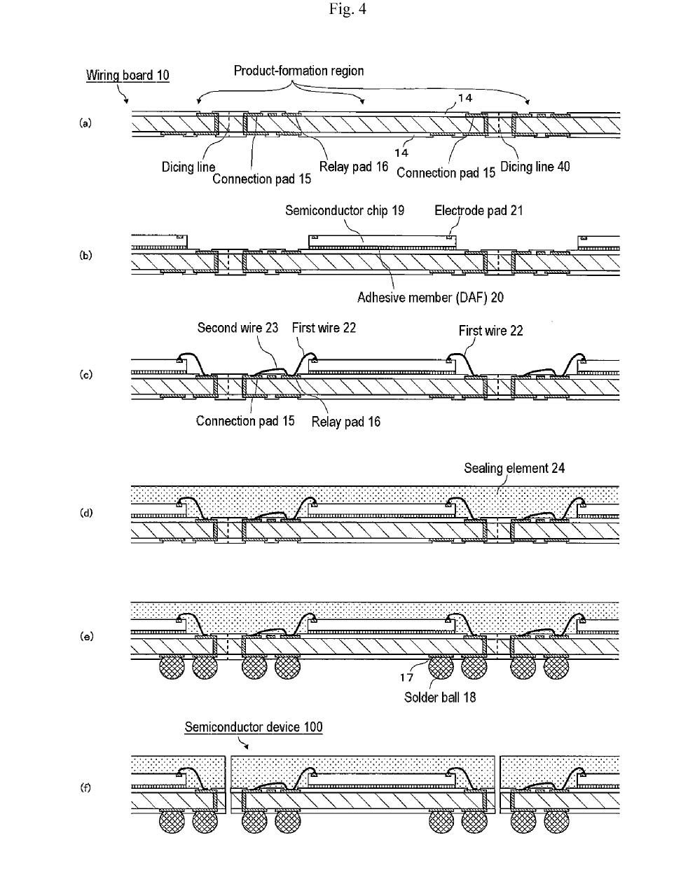

A method for manufacturing the semiconductor device according to the first mode of embodiment of the present invention will be described next with reference to FIG. 4, and also with the aid of FIG. 1 and FIG. 2. Here, FIG. 4 is a view in cross section showing the assembly flow for the semiconductor device 100 according to the first mode of embodiment.

As shown in FIG. 4(a), a wiring board 10 is first of all prepared. The wiring board 10 is formed by an insulating substrate 11, and an insulating film 14, connection pad 15 and relay pad 16 are formed on one surface (the upper surface) thereof.

Meanwhile, an insulating film 14 and lands 17 are formed on the other surface (the lower surface) of the wiring board 10. Dicing lines 40 are further provided on the wiring board 10.

A semiconductor chip 19 which has an adhesive member (DAF) 20 formed on the rear surface thereof is then mounted on the wiring board 10, as shown in FIG. 4(b).

Electrode pads 21 of the semiconductor chip 19 and the relay pad 16 of the wiring board 10 are then electrically connected by means of a first wire 22, as shown in FIG. 4(c). The connection pad 15 and the relay pad 16 of the wiring board 10 are also electrically connected by means of a second wire 23. Here, the second wire 23 is disposed in such a way as to straddle wiring 12.

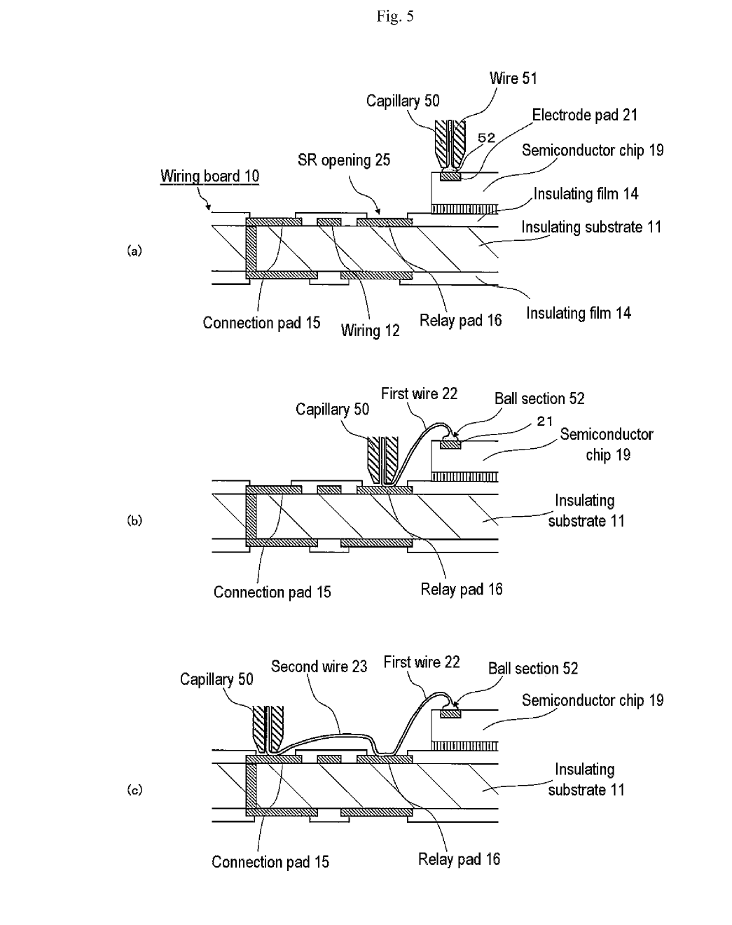

The method for connecting the first wire 22 and the second wire 23 will now be described with reference to FIG. 5. FIG. 5 is a view in cross section showing the processing flow for wire bonding.

The first wire 22 and the second wire 23 comprise Au, for example, and a wire 51 having a ball section 52 formed at a molten tip end in a capillary 50 is first of all thermosonically bonded onto the electrode pad 21 of the semiconductor chip 19, as shown in FIG. 5(a).

Next, as shown in FIG. 5(b), the capillary 50 is moved so that the rear end of the wire 51 is thermosonically bonded onto the relay pad 16 while describing a predetermined loop shape. As a result, the electrode pad 21 of the semiconductor chip 19 and the relay pad 16 are connected by means of the first wire 22.

Next, as shown in FIG. 5(c), the capillary 50 is further moved so that the rear end of the wire 51 is thermosonically bonded onto the connection pad 15. As a result, the relay pad 16 and the connection pad 15 of the semiconductor chip 19 are connected by means of the second wire 23. The processing for the wire bonding is completed in this way.

Next, as shown in FIG. 2(d), the assembly is molded in one batch whereby the sealing element 24 (sealing resin) is formed over one surface of the wiring board 10. The sealing element 24 is formed, for example, by clamping the wiring board 10 between molding dies comprising an upper die and a lower die of a transfer mold apparatus which is not depicted, injecting a heat-curable epoxy resin from a gate into a cavity formed by the upper die and the lower die to fill the cavity, and then heat-curing the resin.

Next, as shown in FIG. 2(e), the solder balls 18 are mounted on the lands 17 on the other surface of the wiring board 10 so as to form external terminals (bump electrodes). In the ball-mounting step, a suction-adhesion mechanism (not depicted) in which a plurality of suction-adhesion holes are formed in alignment with the arrangement of lands 17 on the wiring board 10 is used to hold the solder balls 18 in said suction-adhesion holes, flux is transferred to and formed on the solder balls 18 while they are being held, and the solder balls 18 are then mounted in one batch on the lands 17 of the wiring board 10. After the balls have been mounted, external terminals are formed by reflow.

Next, as shown in FIG. 2(f), the wiring boards 10 on which the external terminals have been formed are cut and separated into individual components at the dicing lines 40. When the boards are diced, the sealing element 24 of the wiring boards 10 is bonded to dicing tape and the wiring boards 10 are supported by the dicing tape. The wiring boards 10 are cut longitudinally and transversely at the dicing lines 40 by means of a dicing blade which is not depicted in order to separate the wiring boards 10 into individual components. After the individual components have been formed, said components are picked up from the dicing tape and a semiconductor device 100 such as that shown in FIG. 2 is obtained.

### Second Mode of Embodiment

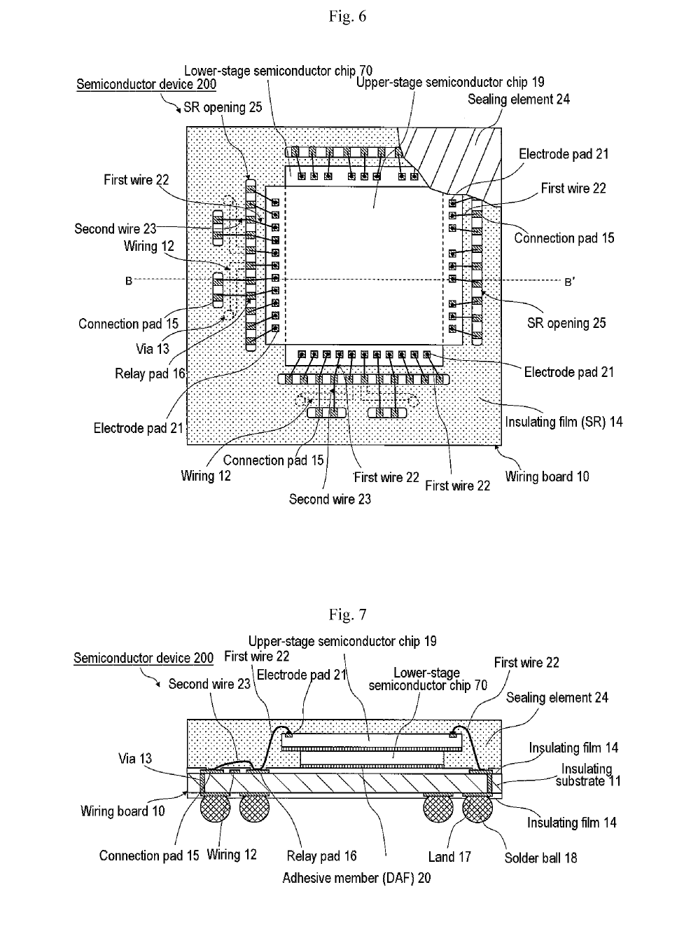

The configuration of a semiconductor device 200 according to a second mode of embodiment of the present invention will be described next with reference to FIG. 6 and FIG. 7. Here, FIG. 6 is a plan view showing the schematic configuration of the semiconductor device 200 according to the second mode of embodiment. FIG. 7 is a view in cross section showing the schematic configuration between B-B′ in FIG. 6. In order to simplify the description, components which are the same as those of the semiconductor device 100 in the first mode of embodiment illustrated in FIG. 1 and FIG. 2 bear the same reference symbols and will not be described again.

The semiconductor device 200 according to the second mode of embodiment of the present invention differs from the semiconductor device 100 according to the first mode of embodiment in that another semiconductor chip 70 (lower-stage semiconductor chip) is disposed between the wiring board 10 and the first semiconductor chip 19 (upper-stage semiconductor chip). The other semiconductor chip 70 (lower-stage semiconductor chip) has substantially the same configuration as the first semiconductor chip 19.

As shown in FIG. 6 and FIG. 7, the two semiconductor chips 19, 70 are mounted on the wiring board 10 of the semiconductor device 200 according to the second mode of embodiment. As mentioned above, the first semiconductor chip 19 constitutes the upper-stage semiconductor chip while the other semiconductor chip 70 constitutes the lower-stage semiconductor chip.

Here, the semiconductor chip 70 is the same kind of chip as the semiconductor chip 19 according to the first mode of embodiment, i.e. a memory chip in which a memory circuit is formed, and a plurality of electrode pads 21 are disposed along the short sides of a rectangular shape, for example. The upper-stage semiconductor chip 19 (memory chip) is stacked in such a way as to be rotated through 90° with respect to the lower-stage semiconductor chip 70 (memory chip). A plurality of DQ-system electrode pads 21 are mainly disposed on one of the short sides of the semiconductor chips 19, 70, while command address-system electrode pads 21 are disposed on the other short side, the number of electrode pads 21 on the short side which is the DQ-system side being greater than the number of electrode pads 21 on the command address-system side.

The semiconductor chips 19, 70 are mounted on the wiring board 10 in such a way that the gap between the short side comprising a larger number of electrode pads 21 and an end of the wiring board 10 is wider than the gap between the opposing short side comprising a smaller number of electrode pads 21 and an end of the wiring board 10.

A relay pad 16 is disposed in locations on the wiring board 10 where the wiring 12 is densely packed, on the DQ side where there are a large number of electrode pads 21 of the respective semiconductor chips 19, 70, in the same way as in the first mode of embodiment, as shown in FIG. 6 and FIG. 7. The relay pad 16 is interposed between the electrode pads 21 of the semiconductor chips 19, 70 and the connection pad 15, and the second wires 23 straddle the other wiring 12.

The second mode of embodiment also achieves the same advantages as the first mode of embodiment, and because the two semiconductor chips 19, 70 are cross-stacked and mounted on the wiring board 10 in an offset manner in such a way as to enlarge the region of densely packed wiring 12, an increase in the capacity of the semiconductor device 200 can be envisioned and there is also a greater degree of freedom in the wiring layout.

### Third Mode of Embodiment

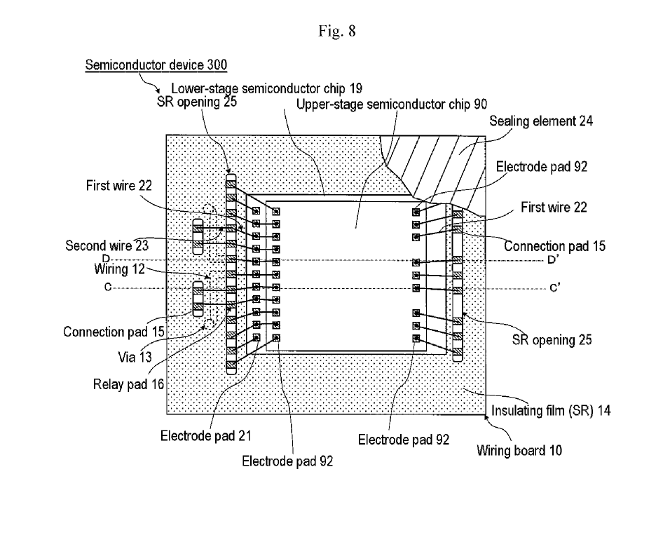

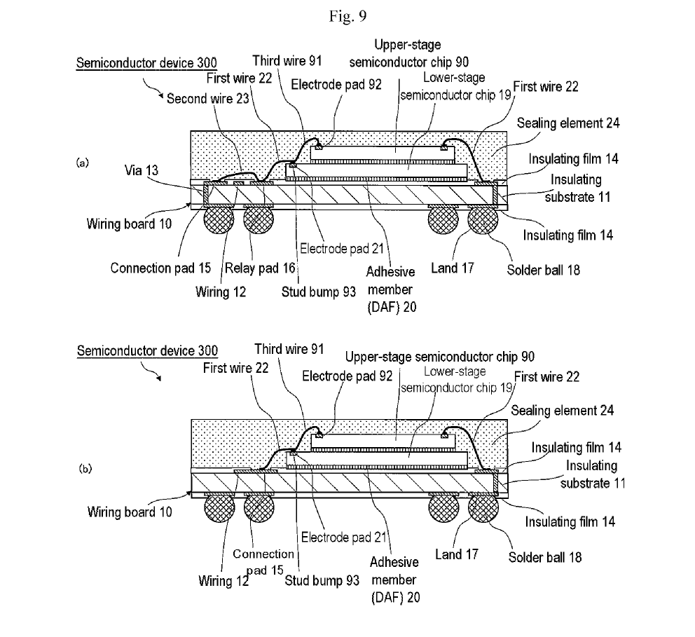

The configuration of a semiconductor device 300 according to a third mode of embodiment of the present invention will be described next with reference to FIG. 8 and FIG. 9. Here, FIG. 8 is a plan view showing the schematic configuration of the semiconductor device 300 according to the third mode of embodiment. FIGS. 9(a) and (b) are views in cross section showing the schematic configuration between C-C′ and between D-D′ in FIG. 8, respectively.

In order to simplify the description, components which are the same as those of the semiconductor device 100 in the first mode of embodiment illustrated in FIG. 1 and FIG. 2 bear the same reference symbols and will not be described again.

The semiconductor device 300 according to the third mode of embodiment of the present invention is constructed in the same way as the semiconductor device 100 according to the first mode of embodiment, but differs in that a plurality of semiconductor chips 19, 90 are mounted on a wiring board 10, and electrode pads 92 and electrode pads 21 forming common pins of the respective semiconductor chips 19, 90 are connected by a third wire 91, as shown in FIG. 8 and FIG. 9. The electrode pads 21, 92 which are independent pins of the respective semiconductor chips 19, 90 such as chip select pins, for example, are connected to a connection pad 15 of the wiring board 10.

According to the third mode of embodiment, the semiconductor chip 90 on which the electrode pads 92 are formed is stacked in this way on the semiconductor chip 19. Here, the semiconductor chip 19 constitutes a lower-stage semiconductor chip while the semiconductor chip 90 constitutes an upper-stage semiconductor chip. Furthermore, a stud bump 93 comprising Au or the like is provided on the electrode pads 21 of the lower-stage semiconductor chip 19.

The third mode of embodiment also achieves the same advantages as the first mode of embodiment, and because the connections can be made using a single wire, including the connections between the semiconductor chip 19 and the semiconductor chip 90, the electrode pads 21, 92 constituting common pins can be connected by a single wire. In addition, a plurality of semiconductor chips 19, 90, and the connection pad 15 and the relay pad 16 of the wiring board 10 are connected by a single wire, so it is possible to reduce the number of times a ball is formed on the wire and the number of times wire cuts are made, so greater processing efficiency can be achieved in the wire bonding step.

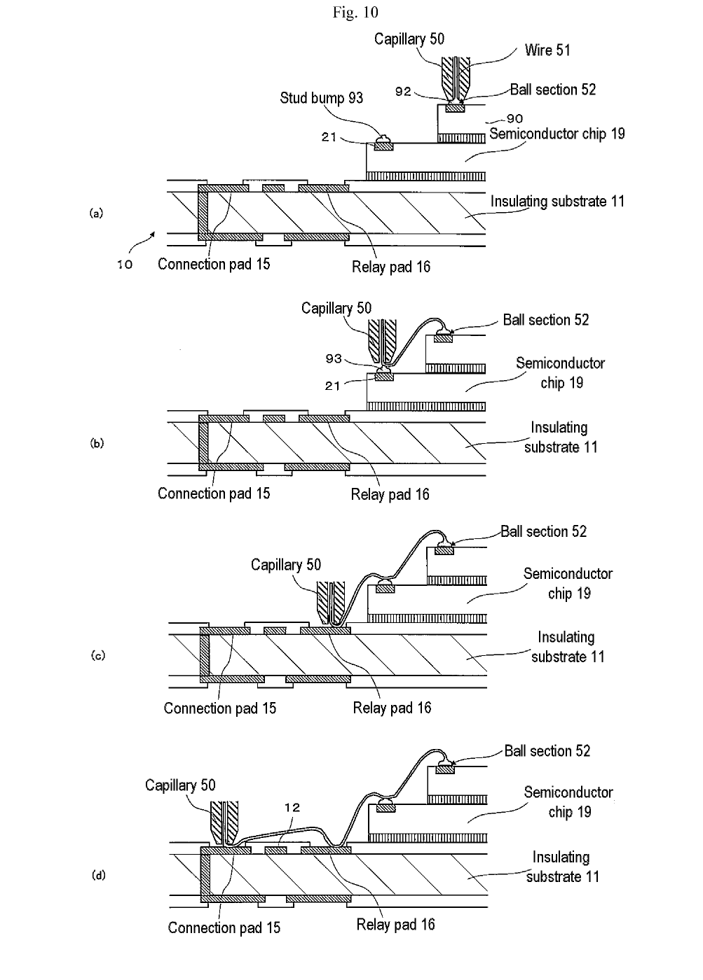

The processing flow for wire bonding according to the third mode of embodiment will be described next with reference to FIG. 10. Here, FIG. 10 is a view in cross section showing the processing flow for wire bonding according to the third mode of embodiment.

The stud bump 93 comprising Au or the like is preformed on the electrode pads 21 of the lower-stage semiconductor chip 19.

As shown in FIG. 10(a), the ball section 52 of a wire 51 in a capillary 50 is bonded by thermosonic bonding onto the electrode pad 92 of the upper-stage semiconductor chip 90.

Next, as shown in FIG. 10(b), a predetermined loop is described and the other end of the wire is bonded by means of thermosonic bonding to the stud bump 93 on the electrode pad 21 of the lower-stage semiconductor chip 19.

Next, as shown in FIG. 10(c), the capillary 50 is moved in such a way that the wire 51 further describes a loop without being cut, whereby the next other end is bonded by means of thermosonic bonding to the relay pad 16 of the wiring board 10.

After this, as shown in FIG. 10(d), the capillary 50 is moved without the wire 51 being cut, whereby the next other end is bonded by means of thermosonic bonding to the connection pad 15 of the wiring board 10 in such a way as to straddle the wiring 12. In this way, the first, second and third wires 22, 23 and 91 are continuously formed, as shown in FIG. 9(a).

The invention devised by the present inventor has been described above on the basis of modes of embodiment, but the present invention is not limited to these modes of embodiment and it goes without saying that various modifications may be made within a scope that does not depart from the essential point thereof.

The modes of embodiment described above relate to a case in which the relay pad 16 is provided on the wiring board 10, but the relay pad 16 may equally be provided on the semiconductor chip 19.

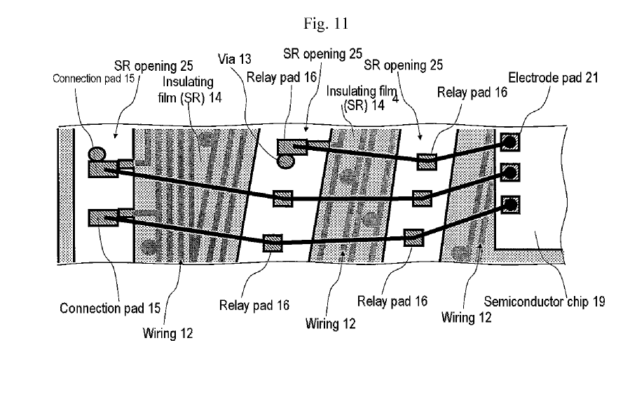

Furthermore, one relay pad 16 is disposed on the wiring board 10 in the case described above, but the electrode pads 21 of the semiconductor chip 19 and the connection pad 15 of the wiring board 10 may equally be connected by way of multiple relay pads 16, as shown in FIG. 11.

Furthermore, a memory chip is mounted in the case described above, but the present invention may be applied to any type of semiconductor chip or chip combination, e.g. a combination of a memory chip and a logic chip etc., or to chips with any pad arrangement, provided that the invention is applied to a semiconductor device having a configuration in which wiring 12 on a wiring board 10 is densely packed.

This application claims the benefit of priority of Japanese Patent Application No. 2013-127216, filed on Jun. 18, 2013, which is herein incorporated by reference in its entirety.

### KEY TO SYMBOLS

10 . . . Wiring board
11 . . . Insulating substrate
12 . . . Wiring
13 . . . Via
14 . . . Insulating film
15 . . . Connection pad
16 . . . Relay pad
17 . . . Land
18 . . . Solder ball
19 . . . Semiconductor chip
20 . . . Adhesive member
21 . . . Electrode pad
22 . . . First wire
23 . . . Second wire
24 . . . Sealing element
25 . . . SR opening
40 . . . Dicing line
50 . . . Capillary
51 . . . Wire
52 . . . Ball section
70 . . . Semiconductor chip (lower stage)
90 . . . Semiconductor chip (upper stage)
91 . . . Third wire
92 . . . Electrode pad
93 . . . Stud bump
100 . . . Semiconductor device
200 . . . Semiconductor device
300 . . . Semiconductor device

1. A semiconductor device comprising:
a wiring board having a first region, and first and second connection pads disposed outside the first region;
a first semiconductor chip which has a first electrode formed on one surface thereof and is mounted in the first region of the wiring board;
a first wire for connecting the first electrode and the first connection pad; and
a second wire for connecting the first connection pad and the second connection pad.

2. The semiconductor device as claimed in claim 1, wherein the first wire and the second wire are continuously formed by a single wire.

3. The semiconductor device as claimed in claim 1, wherein the first wire and the second wire are formed by separate wires.

4. The semiconductor device as claimed in claim 1, wherein:
wiring is further provided outside the first region; and
the second wire is disposed in such a way as to straddle said wiring.

5. The semiconductor device as claimed in claim 4, wherein:
the first semiconductor chip has a substantially rectangular shape;
a plurality of the first electrodes are disposed along first and second short sides of the substantially rectangular shape;
the number of first electrodes disposed on the first short side is greater than the number of first electrodes disposed on the second short side; and
the first connection pad and the second connection pad are connected by way of the second wire on the side of the first short side.

6. The semiconductor device as claimed in claim 5, wherein the side of the first short side constitutes a dense wiring region in which the wiring is densely packed.

7. The semiconductor device as claimed in claim 6, wherein:
the first connection pad forms a relay pad in the dense wiring regions; and
the second wire is connected to the second connection pad via the relay pad while passing over the wiring.

8. The semiconductor device as claimed in claim 7, wherein the first wire is connected between the first electrode and the relay pad in a bent state.

9. The semiconductor device as claimed in claim 5, wherein:
another semiconductor chip having substantially the same configuration as the first semiconductor chip is disposed between the wiring board and the first semiconductor chip;
the first semiconductor chip is stacked in such a way as to be rotated through 90° with respect to said other semiconductor chip; and
the gap between the first short side and an end of the wiring board is wider than the gap between the second short side and an end of the wiring board.

10. The semiconductor device as claimed in claim 1, further comprising:
a second semiconductor chip which has a second electrode formed on one surface thereof and is stacked on the first semiconductor chip; and
a third wire for connecting the first electrode and the second electrode.

11. The semiconductor device as claimed in claim 7, wherein a plurality of the relay pads are provided between the first electrode and the second connection pad.

12. A method for manufacturing a semiconductor device, comprising:
preparing a wiring board having, on one surface, a first region, and first and second connection pads disposed outside the first region;
mounting a first semiconductor chip which has a first electrode formed on one surface thereof in the first region of the wiring board;
connecting the first electrode and the first connection pad by means of a first wire; and
connecting the first connection pad and the second connection pad by means of a second wire.

13. The method for manufacturing a semiconductor device as claimed in claim 12, further comprising forming a sealing resin on said one surface of the wiring board in such a way as to cover at least the first semiconductor chip.

14. The method for manufacturing a semiconductor device as claimed in claim 12, wherein the first wire and the second wire are continuously formed by a single wire.

15. The method for manufacturing a semiconductor device as claimed in claim 12, wherein the first wire and the second wire are formed by separate wires.

16. The method for manufacturing a semiconductor device as claimed in claim 12, further comprising:
forming wiring outside the first region; and
forming the second wire in such a way as to straddle said wiring.

17. The method for manufacturing a semiconductor device as claimed in claim 12, further comprising:
stacking a second semiconductor chip having a second electrode formed on one surface thereof on the first semiconductor chip; and
connecting the first electrode and the second electrode by means of a third wire.

18. The method for manufacturing a semiconductor device as claimed in claim 17, further comprising:
preforming a stud bump on the first electrode of the first semiconductor chip;
bonding a ball section of a wire in a capillary by thermosonic bonding on the second electrode of the second semiconductor chip;
moving the capillary whereby the ball section is bonded by means of thermosonic bonding to the stud bump in such a way that the wire describes a predetermined loop; and
moving the capillary in such a way that the wire further describes a loop without being cut, whereby the wire is bonded by means of thermosonic bonding to the first and second connection pads on the wiring board, and the first, second and third wires are continuously formed as a result.
